(19) United States
(12) Patent Application Publication
(10) Pub. No.: US 2026/0018509 A1
(43) Pub. Date: Jan. 15, 2026

(54) ELECTRONIC DEVICE WITH REDUCED ELECTRIC FIELDS IN SUPERFICIAL LAYERS AND FABRICATION METHOD THEREOF

(71) Applicant: STMicroelectronics International N.V., Geneva (CH)

(72) Inventors: Antonella MILANI, Cusano Milanino (IT); Elisabetta PIZZI, Limbiate, Milano (IT); Vincenzo PALUMBO, Milano (IT)

(73) Assignee: STMicroelectronics International N.V., Geneva (CH)

(21) Appl. No.: 19/260,780

(22) Filed: Jul. 7, 2025

(30) Foreign Application Priority Data
Jul. 9, 2024 (IT) 102024000015754

(51) Int. Cl. H01L 23/522

(52) U.S. Cl. CPC H01L 23/5225

(57) ABSTRACT

A galvanic-isolation device includes a metal cap layer extending above a top metal layer of a galvanic isolation module. The metal cap layer is in electrical contact with the top metal layer at a central portion of the top metal layer. A buffer layer separates the metal cap layer from the top metal layer at peripheral portions of the top metal layer. Electric field peaks at edges of the metal cap layer and the top metal layer are decoupled from one another by recessing the lateral edges of the metal cap layer by a distance (for example, greater than one micrometer) from the corresponding edges of the top metal layer.

### PRIORITY CLAIM

This application claims the priority benefit of Italian Application for Pat No. 102024000015754 filed on Jul. 9, 2024, the content of which is hereby incorporated by reference in its entirety to the maximum extent allowable by law.

### TECHNICAL FIELD

Embodiments herein relate to an electronic device and a manufacturing method thereof and, in particular, to a Galvanic isolation device featuring a reduced intensity of electric fields in superficial layers.

### BACKGROUND

Galvanic isolation (GI) is known to provide isolation of different functional sections of an electrical system to prevent current flow by avoiding a direct conduction path. Galvanic isolation can be achieved, in particular, with capacitive or inductive coupling.

FIG. 1 schematically illustrates a portion of a Galvanic isolation (GI) based device 1, in a triaxial system of axes x, y, z orthogonal to each other, in a lateral sectional view on the xz plane. In particular, the GI device 1 is a capacitively coupled GI device.

The GI device 1 comprises a solid body 10. The solid body 10 includes a substrate 110, a first dielectric layer 112 extending on the substrate 110, a bottom metal layer 114 extending within the first dielectric layer 112 at a first height along the z axis, a top metal layer 116 extending within the first dielectric layer 112 at a second height along the z axis greater than the first height. A surface 116a of the top metal layer 116 is coplanar with a surface 112a of the first dielectric layer 112, both surfaces lying on the xy plane. Two lateral surfaces 116b and 116c of the top metal layer 116 extend in the yz plane and are in direct contact with the first dielectric layer 112. The two lateral surfaces 116b, 116c are also denoted as “top metal edges” 116b, 116c.

The bottom metal layer 114, the first dielectric layer 112 and the top metal layer 116 form a capacitor through which different portions of an electrical system (not shown) can be coupled for the transmission of electrical signals, at the same time being isolated from each other to avoid direct current flows.

GI device 1 further comprises a dielectric or insulating buffer layer 120 extending above and in contact with the top metal layer 116 (i.e., on the top surface 116a), at two peripheral portions of the top surface 116a, and above and in contact with the top surface 112a of the first dielectric layer 112 laterally to the top metal layer 116. A metal layer 118, also referred to as “capping layer” and in the following, denoted as “cap layer 118”), typically made of aluminum, extends above and in contact with a central portion (comprised between the two peripheral portions of the top surface 116a) of the top surface 116a and above and in contact with the buffer layer 120. Two lateral surfaces 118b and 118c of the cap layer 118 extend in the yz plane and are also denoted as “cap edges” 118b, 118c. The function of the cap layer 118 is to provide a suitable surface for the bonding of external wiring elements. The top metal edge 116b and the cap edge 118b extend aligned together parallel to the z axis. Analogously, the top metal edge 116c and the cap edge 118c also extend aligned together parallel the z axis. In other words, the top metal edge 116b and the cap edge 118b lie on a same plane parallel to the yz plane, and the top metal edge 116c and the cap edge 118c lie on a same respective plane parallel to the yz plane. A second dielectric layer 122 extends above the buffer layer 120 and the cap layer 118 and includes a passing hole 119 that is at least partially aligned, along the z axis, with the central portion of the top surface 116a; a top surface 118a of the cap layer 118 is exposed through the passing hole 119. The GI device 1 further comprises an organic passivation layer 124 extending above the second dielectric layer 122; a passing hole 121 extends through the organic passivation layer 124 at least partially aligned with the passing hole 119. A bonding structure 126 extends through the passing holes 119, 121, reaching and electrically contacting the cap layer 118 at the top surface 118a. For instance, wire bonding can be used. A molding compound (MC) layer 125 fills the passing holes 119, 121, enclosing and protecting the bonding structure 126 within the passing holes 119, 121; the MC layer 125 may also extend above the organic passivation layer 124. The stack formed by the organic passivation layer 124 and the MC layer 125 is also called “polymeric stack”.

The buffer layer 120 is typically made of silicon oxide or silicon nitride and has a thickness in the range 400 to 800 nm. The second dielectric layer 122 is typically of silicon oxide or silicon nitride and has a thickness in the range of 2 to 6 μm.

In the technical field of GI devices, it is known that high electric fields (i.e., electric fields with values higher than 0.8 MV/cm) and high voltages (i.e., voltages higher 1000 V, preferably greater than 1500 V) may be the cause of ageing mechanisms that can be observed during reliability tests. These ageing mechanisms mainly affect the polymeric stacks 124, 125 in regions located in correspondence of peaks of electric field.

Peaks of electric field generate at the top metal edges 116b, 116c and at the cap edges 118b, 118c and extend into the polymer stack 124, 125. The electric field intensity in the polymer stack 124, 125 depends on the thickness of the second dielectric layer 122. A higher thickness of the second dielectric layer 122 allows to sustain higher electric fields and therefore to increase the ageing mechanism Time-To-Failure (TTF).

Therefore, one solution is to increase the thickness of the second dielectric layer 122. However, this solution may cause drawbacks in the manufacturing process, including: thicker photoresists to be exposed, more time-consuming and difficult etching resulting in a complete consumption of the photoresists and more complex wet removal schemes to be implemented after the etching to clean the structures. The overall consequence of these drawbacks are a reduced fabrication yield and increased production costs.

There is accordingly a need in the art to provide an electronic device and a manufacturing method thereof which overcome the foregoing drawbacks.

### SUMMARY

In an embodiment, an electronic device comprises: a solid body comprising a metallic structure having a top surface lying on a plane and having a thickness along a first direction orthogonal to the top surface; a metal layer on the metallic structure, comprising a central portion, a first peripheral portion and a second peripheral portion, the first and the second peripheral portion being at opposite ends of the central portion, the central portion being in direct electrical contact with the surface of the metallic structure, the first and the second peripheral portion being in physical and electrical continuity with the central portion; and a first insulating layer interposed between the metallic structure and the first and second peripheral portions of the metal layer.

The metallic structure has at least a first lateral surface, transverse to said plane, externally delimiting a corresponding portion of the metallic structure; and the first peripheral portion of the metal layer has a respective first lateral surface, transverse to said plane.

The first lateral surface of the metal layer is recessed from the first lateral surface of the metallic structure along a second direction orthogonal to the first direction by a first distance. This first distance may, for example, be equal to, or greater than, one micrometer.

In an embodiment, a method of manufacturing an electronic device comprises the steps of: providing a solid body comprising a metallic structure having a top surface lying on a plane and having a thickness along a first direction orthogonal to the top surface; forming a first insulating layer on the surface of the metallic structure; forming a first passing hole through the first insulating layer up to a corresponding portion of the surface of the metallic structure; and forming a metal layer within the first passing hole and on the first insulating layer. The forming of the metal layer comprises: forming a central portion in direct electrical contact with the surface of the metallic structure through the first passing hole, forming a first peripheral portion at an end of the central portion and on the first insulating layer, and forming a second peripheral portion at an opposite end of the central portion and on the first insulating layer, the first and the second peripheral portion being formed in physical and electrical continuity with the central portion.

The metallic structure has at least a first lateral surface transverse to said plane, externally delimiting a corresponding portion of the metallic structure; and the first peripheral portion of the metal layer has a respective first lateral surface transverse to said plane.

The first lateral surface of the metal layer is formed recessed from the first lateral surface of the metallic structure along a second direction orthogonal to the first direction by a first distance. This first distance may, for example, be equal to, or higher than, one micrometer.

### BRIEF DESCRIPTION OF THE DRAWINGS

For a better understanding of the present invention, some embodiments thereof are now described, purely by way of non-limiting example, with reference to the attached drawings, wherein:

FIG. 1 schematically illustrates, in a lateral sectional view, a portion of a galvanic insulation device;

FIG. 2A schematically illustrates, in a lateral cross-sectional view, a portion of an electronic device, in particular a galvanic insulation (GI) device;

FIG. 2B illustrates, in a top-plan view, a portion of the GI device of FIG. 2A, wherein the cross-sectional view of FIG. 2A is taken along the cut line II-II of FIG. 2B;

FIG. 3 schematically illustrates, in lateral cross-sectional view, a portion of a GI device; and

FIGS. 4A-4G illustrate, in lateral cross-sectional view, manufacturing steps of the GI device of FIG. 2A (analogously, GI device of FIG. 3), limited to the manufacturing of elements of the GI device that are relevant to the embodiments.

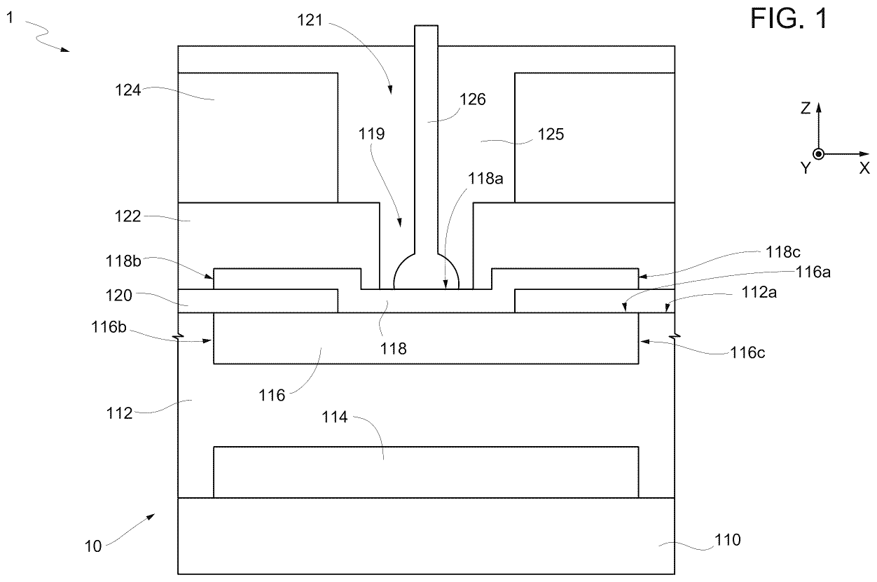

### DETAILED DESCRIPTION

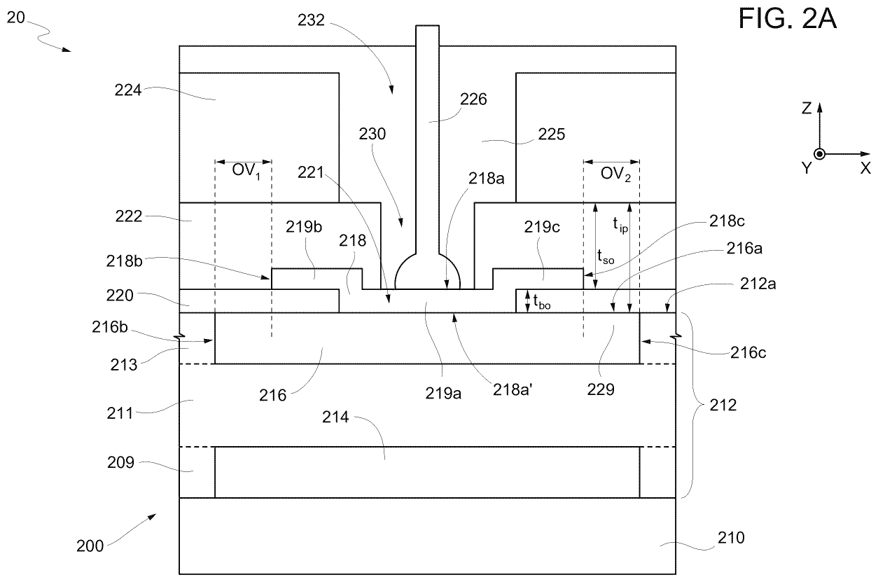

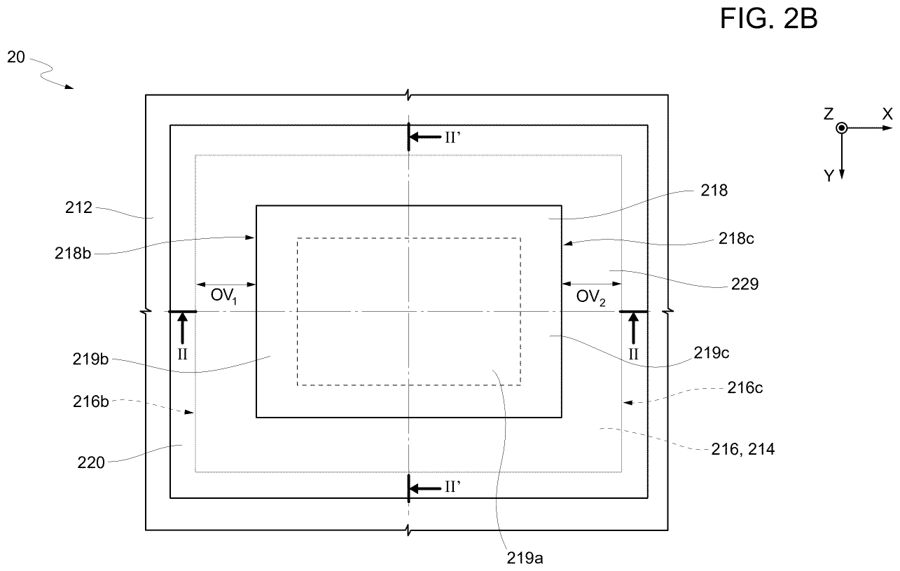

FIG. 2A schematically illustrates a portion of an electronic device 20 including a Galvanic Isolator (GI) module.

The electronic device 20 is in the following also referred to as GI device 20. The GI device 20 is represented in a triaxial system of axes x, y, z orthogonal to each other, in lateral cross-sectional view parallel to the xz plane.

FIG. 2B illustrates, in a top-plan view on xy plane, a portion of the GI device 20 of FIG. 2A, wherein the cross-sectional view of FIG. 2A is taken along the cut line II-II of FIG. 2B. FIG. 2B illustrates only some features of FIG. 2A, for a better understanding and improved clarity of the drawing.

The GI device 20 comprises a solid body 200. In particular, the solid body 200 includes a substrate 210, for example of semiconductor material such as silicon (Si), silicon carbide (SiC of any polytype), sapphire (Al₂O₃), GaN. The substrate 210 may also include a plurality of layers epitaxially grown or deposited, for example via chemical vapor deposition (CVD) or physical vapor deposition (PVD), and patterned, for example via different photolithography and etching steps.

The solid body 200 further includes: a bottom metal layer 214 (e.g., made of copper or aluminum) extending on a superficial portion of the substrate 210; a first intermetal dielectric layer 209 extending on the substrate 210 laterally to the bottom metal layer 214; an intermediate dielectric layer 211 extending on the first intermetal dielectric layer 209 and on the bottom metal layer 214; a top metal layer 216 (e.g., made of copper) extending on a superficial portion of the intermediate dielectric layer 211; and a second intermetal dielectric layer 213 extending on the intermediate dielectric layer 211 laterally to the top metal layer 216. The bottom and top the metal layers 214, 216 are at least in part overlapping to one another along the z axis. The intermediate dielectric layer 211 extends between the bottom and top the metal layers 214, 216 such that the bottom and top the metal layers 214, 216 are capacitively coupled together, thus forming a capacitor of the galvanic isolation module. In one embodiment, different portions of an electrical system (not shown) can be coupled through such capacitor for transmitting, during use, electrical signals while avoiding direct current flows.

Exemplarily, the intermediate dielectric layer 211 and the second intermetal dielectric layer 213 are a single layer (i.e., formed in a single deposition step), with the top metal layer 216 inserted in a recess formed in the dielectric material. Exemplarily, the first intermetal dielectric layer 209 and the intermediate dielectric layer 211 are two distinct layers (i.e., formed in two distinct deposition steps). In the following disclosure, the first intermetal dielectric layer 209, the intermediate dielectric layer 211 and the second intermetal dielectric layer 213 are referred to as first dielectric layer 212. The first intermetal dielectric layer 209, the intermediate dielectric layer 211 and the second intermetal dielectric layer 213 may be of a same dielectric material, or of respective dielectric (or otherwise insulating) materials, including silicon oxide, silicon nitride, etc. The bottom metal layer 214 extends within the first dielectric layer 212 at a first height along the z axis, and the top metal layer 216 extends within the first dielectric layer 212 at a second height, greater than the first height, along the z axis.

In one embodiment, a surface 216a of the top metal layer 216 is coplanar with a surface 212a of the first dielectric layer 212, and parallel to the xy plane; therefore, surfaces 212a and 216a form, as a whole, a surface of the solid body 200.

In the cross-section view of FIG. 2A, two lateral surfaces 216b and 216c of the top metal layer 216 depart from the surface 216a towards the bottom metal layer 214 at opposite sides, along the x axis, of the top metal layer 216, parallel to the yz plane. In particular, the lateral surfaces 216b and 216c are in direct contact with the first dielectric layer 212. The two lateral surfaces 216b, 216c are, in the following, also referred to as top metal edges 216b, 216c. In general, the two lateral surfaces 216b, 216c extend transverse to the plane on which the surface 216a of top metal layer 216 lies, that is they are transverse to the xy plane or to a plane parallel to the xy plane.

GI device 20 further comprises a buffer layer 220 (made of dielectric or insulating material, such as silicon oxide or silicon nitride) extending above the surface 216a of the top metal layer 216 and, optionally, above the surface 212a of the first dielectric layer 212 laterally to the top metal layer 216.

In an embodiment, the buffer layer 220 is in direct contact with the top metal layer 216 and the first dielectric layer 212 at the respective surfaces. In another embodiment, a first adhesion layer (not shown in FIG. 2A) extends between the surface 216a of the top metal layer 216 and the buffer layer 220, in direct contact with the top metal layer 216 and the buffer layer 220. The first adhesion layer is, for example, made of nitride material, e.g., silicon nitride. The first adhesion layer could have a double function of both favoring the adhesion between the buffer layer 220 and the top metal layer 216 and capping the top metal layer (i.e., avoiding the migration of metal material in the buffer layer 220)

The buffer layer 220 has a through opening 221, through which a portion of the surface 216a of the top metal layer 216 is exposed.

A conductive capping layer 218 (in the following, referred to as “cap layer” 218) extends in part above the buffer layer 220 (portions 219b and 219c of the cap layer 218), and in part within the through opening 221 of the buffer layer 220 (portion 219a of the cap layer 218), electrically contacting the top metal layer 216. In particular, the conductive cap layer 218 is made of, or includes, one or more metal materials, for example it is made of aluminum or aluminum alloy. The portion 219b is in electrical connection with the portion 219a on one side of the portion 219a; the portion 219c is in electrical connection with the portion 219a on another, opposite, side of the portion 219a. The portions 219a-219c are formed as one single layer extending with electrical and physical continuity.

In one embodiment, to improve the manufacturing process, the portion 219b has a length, along the x axis, of at least 2 μm; analogously, also the portion 219c has a length, along the x axis, of at least 2 μm.

The cap layer 218 has a bottom surface 218a′ directly facing the top metal layer 216 and a top surface 218a opposite to the bottom surface 218a′ along the z axis. The cap layer 218 terminates, at one hand, with a first lateral surface 218b and, at the other hand, with a second lateral surface 218c. The first lateral surface 218b and the second lateral surface 218c connect the top surface 218a to the bottom surface 218a′. In particular, the lateral surfaces 218b, 218c extend parallel to the yz plane. The lateral surfaces 218b, 218c are also denoted, in the following, as “cap edges” 218b, 218c. In general, the two lateral surfaces 218b, 218c extend transverse to the plane on which the surface 218a of cap layer 218 lies, that is they are transverse to the xy plane or to a plane parallel to the xy plane.

The function of the cap layer 218 is to provide a suitable surface for the bonding (e.g., by means of wire bonding).

The cap edges 218b, 218c are not aligned, along the z axis, with the top metal edges 216b, 216c, respectively. In detail, as illustrated in FIG. 2B, in a top-plan view on the xy plane, the cap layer 218 is completely contained within the top metal layer 216 in such a way that the cap layer 218 covers only a central portion of the top metal layer 216, leaving an outer portion 229 of the top metal layer 216 uncovered (the cap layer 218 is absent above the outer portion 229 of the top metal layer 216). The outer portion 229 of the top metal layer 216 completely surrounds, in the top-plan view, the central portion of the top metal layer 216.

The outer portion 229 of the top metal layer 216 has a dimension OV₁, along the x axis, between the cap edge 218b and the top metal edge 216b. The outer portion of the top metal layer 216 has a dimension OV₂, along the x axis, between the cap edge 218c and the top metal edge 216c.

In other words, OV1 and OV2 are distances, along the x axis and in a top-plan view, between respectively the cap edge 218b and the top metal edge 216b, and the cap edge 218c and the top metal edge 216c.

Preferably, distances OV1 and OV2 are greater than or equal to 1 μm. More preferably, distances OV1 and OV2 are greater than or equal to 2 μm.

The values of distances OV₁ and OV₂ can vary in the range 1-50 μm, in particular in the range 2-31 μm, even more preferably in the range 10-15 μm. The distances may, for example, be substantially equal to either 2 or 31 μm, where substantially equal means within a range of +/−3% of the target value.

In one non-limiting embodiment, distance OV₁ equals distance OV₂.

In general, the above disclosed arrangement of the cap edge 218b and the top metal edge 216b allows to decouple electric fields peaks located at the cap edge 218b from the electric fields peaks located at the top metal edge 216b. Analogously, the cap edge 218c and the top metal edge 216c are reciprocally arranged according to the above disclosed arrangement of the cap edge 218b and the top metal edge 216b, thus allowing to decouple electric fields peaks located at the cap edge 218c from the electric fields peaks located at the top metal edge 216c.

The electric peaks decoupling is, in particular, obtained by recessing the top metal edges 216b, 216c from the respective cap edges 218b, 218c by the distance OV1 and distance OV2 quantities.

It is to be noted that the cross-sectional view of FIG. 2A is taken along the section line II-II of FIG. 2B, which is parallel to the x axis. However, a same or analogous cross-section is present, according to an embodiment, along a section line II′-II′ parallel to the y axis. The previous disclosure therefore applies analogously for such a cross-sectional view along the line II'-II', in particular in relation to the presence of dimensions, along the y axis, corresponding to distances OV₁ and OV₂.

In one embodiment, the GI device 20 additionally includes a second dielectric layer 222 extending above the buffer layer 220 and the cap layer 218 and including a passing hole 230 that is at least partially aligned, along the z axis, with the portion 219a of the cap layer 218 (i.e., the portion of the cap layer 218 directly contacting the top metal layer 216). The surface 218a of the portion 219a is thus exposed through the passing hole 230.

In one embodiment, the GI device 20 further comprises an organic passivation layer 224 extending above the second dielectric layer 222 and a passing hole 232 extending through the organic passivation layer 224 at least partially aligned with the passing hole 230.

Exemplarily, a bonding structure 226 extends through the passing holes 230, 232, reaching and electrically contacting the cap layer 218 at the portion 219a. For instance, wire bonding can be used. A molding compound (MC) layer 225 at least partially fills the passing holes 230, 232, enclosing and protecting the bonding structure 226 within the passing holes 230, 232. The MC layer 225 may also extend above the organic passivation layer 224. The stack formed by the organic passivation layer 224 and the MC layer 225 is also called “polymeric stack” 224, 225.

The buffer layer 220 is, for example, made of silicon oxide or silicon nitride. In the embodiment of FIGS. 2A-2B, the buffer layer 220 has a thickness “t_{bo}”, along the z axis, for example in the range of 400 to 800 nm. The second dielectric layer 222 is, for example, made of silicon oxide or silicon nitride. The second dielectric layer 222 has a thickness “tₛₒ” for example in the range of 2 to 6 μm.

In an embodiment, a second adhesion layer (not shown) physically couples together the organic passivation layer 224 and the second dielectric layer 222. The second adhesion layer (which could further have a sealing function) is, for example, made of nitride material, e.g., silicon nitride.

In one exemplary embodiment: the bottom metal layer 214 is made of copper and has a thickness in the range of 0.5 to 1.5 μm; the first dielectric layer 212 is made of silicon oxide and has a total thickness in the range of 4 to 20 μm, for example 10 μm; the top metal layer 216 is made of copper and has a thickness in the range of 2 to 4 μm; the cap layer 218 is made of aluminum and has a thickness in the range 0.5 to 1.5 μm, preferably 1 μm; the distances OV1, OV2 are in the range of 10 to 15 μm, in particular 14 μm; the buffer layer 220 is made of silicon oxide and has the thickness “t_{bo}” in the range of 400 to 800 nm, in particular 600 nm; and the second dielectric layer 222 is made of silicon oxide and has the thickness “tₛₒ” in the range of 2 to 6 μm, in particular 4.5 μm.

The buffer layer 220 and the second oxide layer 222 form, as a whole, an “inorganic passivation”. The inorganic passivation has a thickness “tᵢₚ”, along the z axis, given by the sum of t_{bp} and tₛₒ. The inorganic passivation thickness tᵢₚ is in the range of 2.4 to 6.8 μm, in particular 5.1 μm.

The organic passivation layer 224 is, for example, made of polyimide and has a thickness in the range of 5 to 20 μm, in particular 9 μm. The MC layer 225 is made of polymeric material (e.g., composite polymeric material, with oxide filler) and has a thickness in the range of 7 to 26 μm.

By introducing the OV₁, OV₂ distances, a decoupling of the electric fields located at the two metallic edges on each side of the device (i.e., cap edge 218b and top metal edge 216b on one side, the cap edge 218c and top metal edge 216c on the other side) is obtained. Hence, main electric field peaks are confined at the top metal edges 216b, 216c. Due to the presence of the outer region 229, not covered by the cap layer 218, the inorganic passivation thickness tᵢₚ, greater than the second dielectric layer 222 thickness tₛₒ, separates the top metal edges 216b, 216c (i.e., the zone of highest electric field intensity) from the polymeric stack 224, 225, with a consequent reduction of the electric field intensity in the polymeric stack 224, 225.

In this way, a reduction of the electric field intensity in the polymeric stack 224, 225 is obtained. The electric field intensity in the polymeric stack 224, 225 is reduced and the TTF in reliability tests is improved.

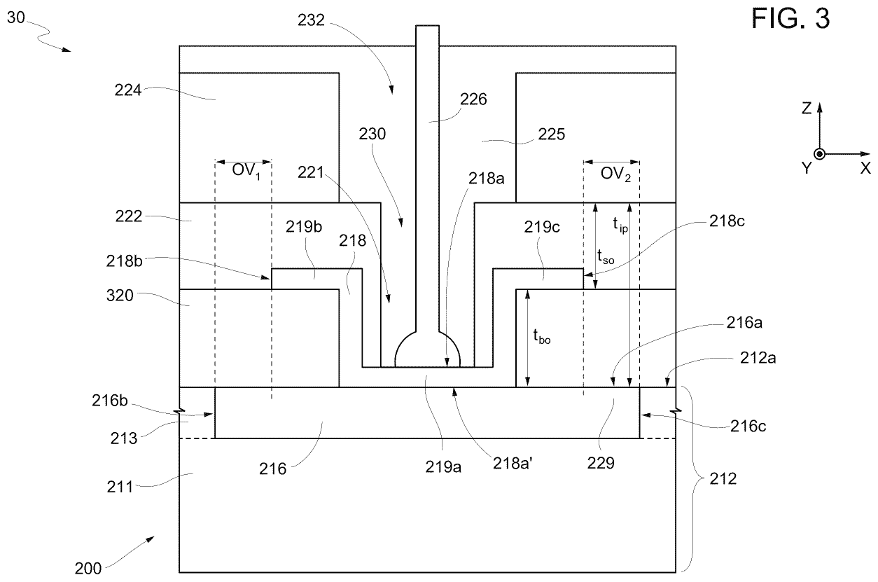

With reference to FIG. 3, a further embodiment is described. In FIG. 3, an upper portion of a GI device 30 is illustrated in the same triaxial system of axes x, y, z of FIG. 2A, and in the same lateral sectional view of FIG. 2A. In FIG. 3, elements of the GI device 30 that are in common with the GI device 20 of FIG. 2A are indicated with the same reference numerals and are not further described.

In the GI device 30, the thickness t_{bo} of the buffer layer 220 is increased, thus forming a corresponding buffer layer 320 having an increased thickness t_{bo}′ that is in the range of 2 to 6μm, in particular 4 μm. The thickness t_{bo}′ of the buffer layer 320 allows reaching a total inorganic passivation thickness tᵢₚ′, separating the top metal edges 216b from the polymeric stack, in the range of 4 to 12 μm, in particular 8.5 μm. In this way, since the inorganic passivation thickness tᵢₚ′ is increased with respect to the embodiment of FIG. 2A-2B, it is possible to further reduce the effect of the electric fields acting on the polymeric stack 224, 225, thus improving the operational life of the device and/or improving the electrical performance.

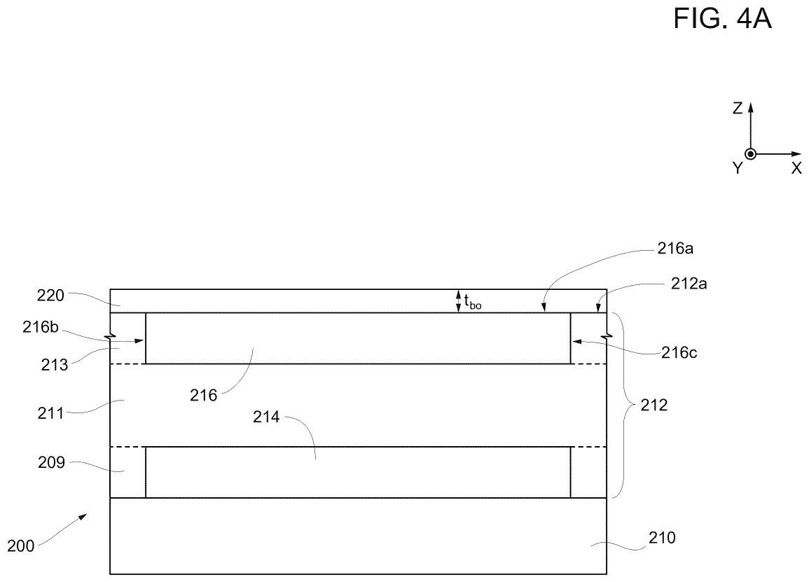

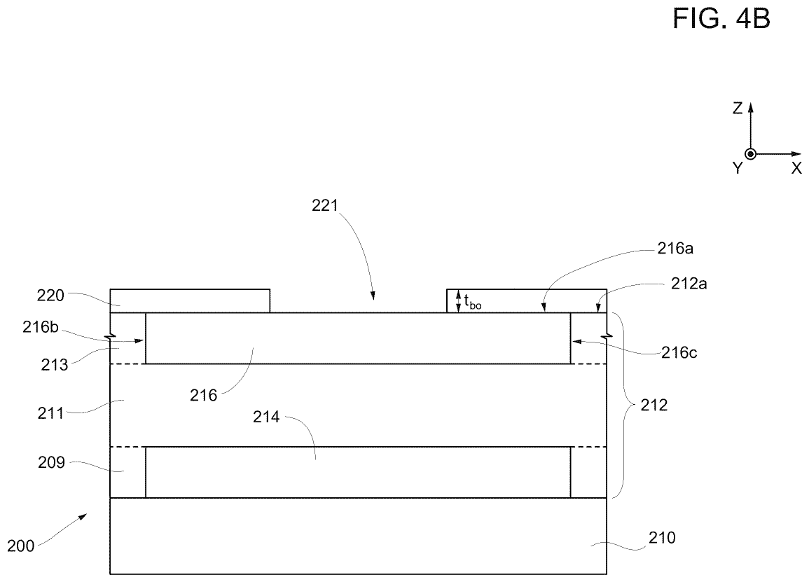

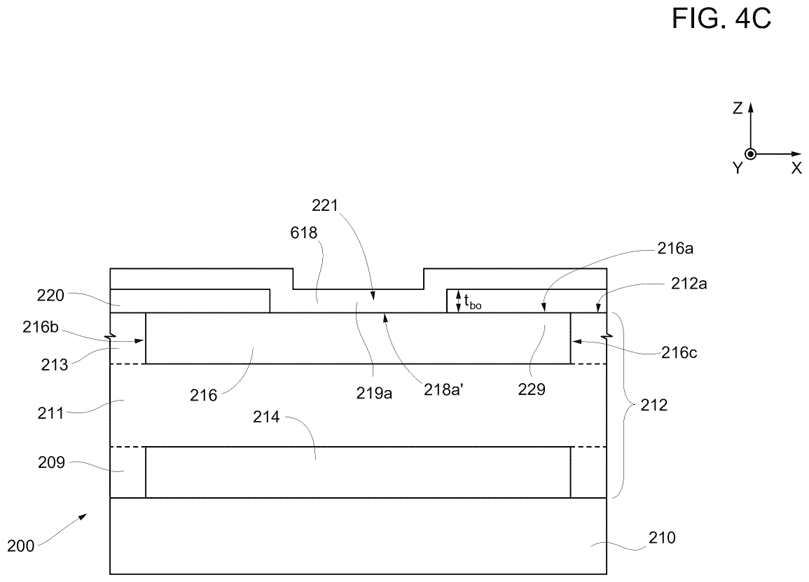

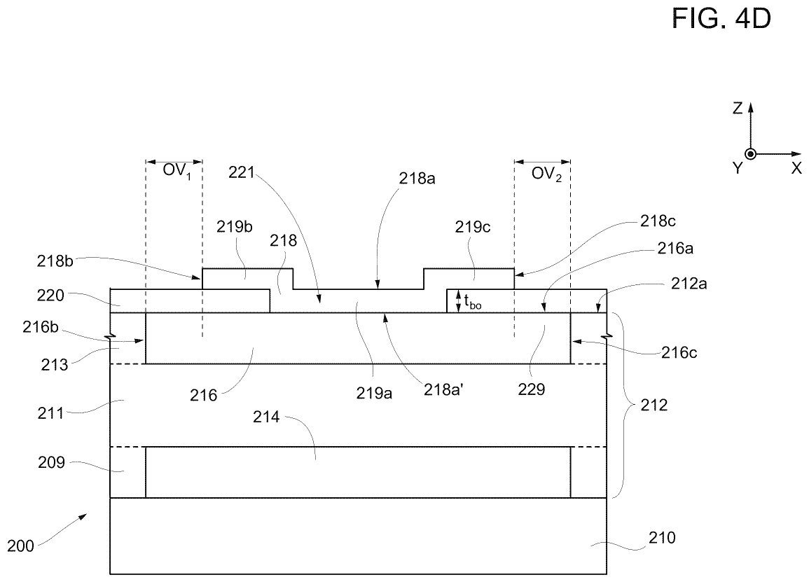

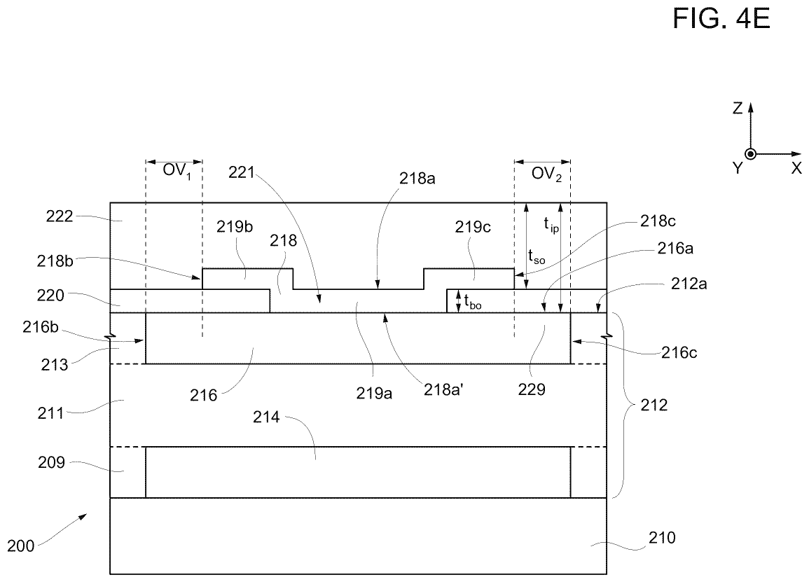

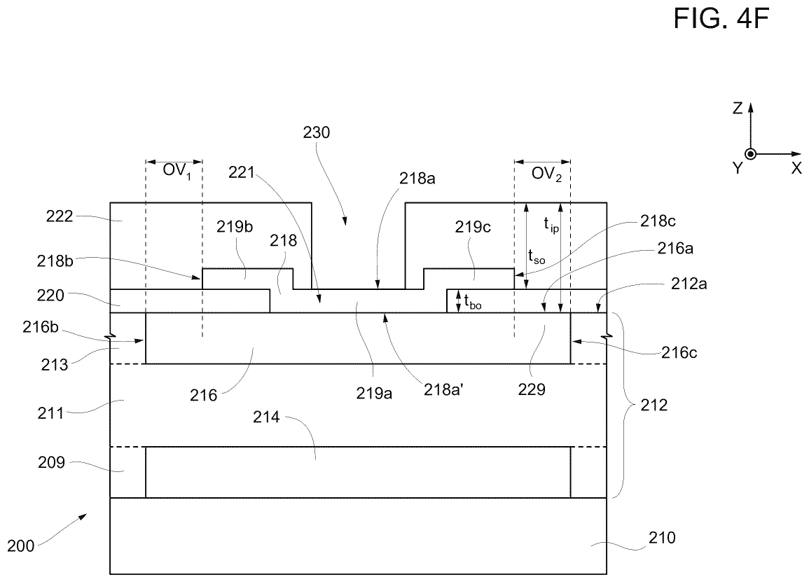

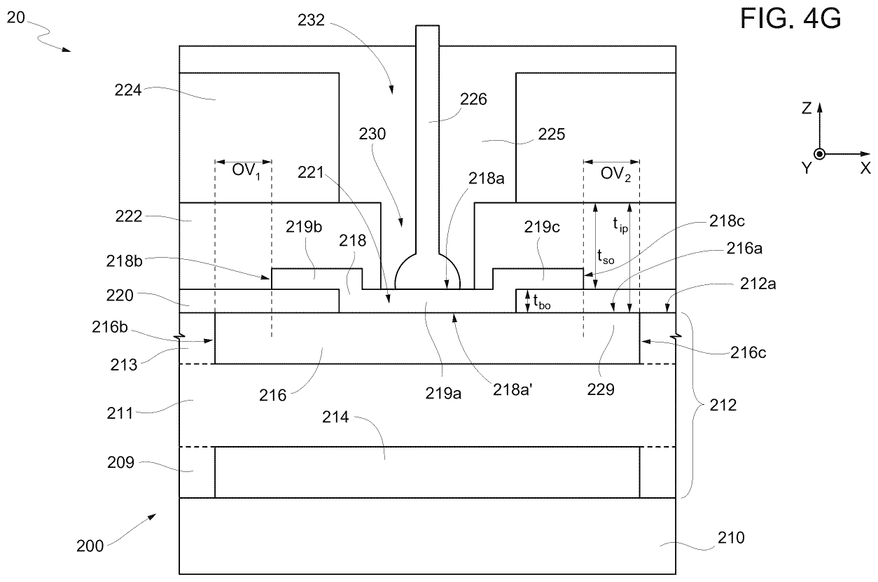

With reference to FIGS. 4A-4G, manufacturing steps of the portion of the GI device 20 (analogously, GI device 30) are now described, limited to the formation of elements of the GI device 20 that are relevant. FIGS. 4A-4G are lateral cross-sectional views on the xz plane.

With reference to FIG. 4A, after having formed the solid body 200 in a per se known manner (e.g., by one or more epitaxial growths or depositions using PVD or CVD and one or more masked etching steps on the substrate 210) the buffer layer 220 is deposited by means of a known deposition process (for example, by CVD or by atomic layer deposition (ALD)).

As discussed, in one embodiment (GI device 20, FIG. 2A), the buffer layer 220 has a thickness t_{bo} in the range of 400 to 800 nm, in particular 600 nm.

In another embodiment (GI device 30, FIG. 3), the buffer layer 320 has a thickness t_{bo}′ in the range of 2 to 6 μm, in particular 4 μm.

With reference to FIG. 4B, a masked etching step is performed to remove selective portions of the buffer layer 220. The through opening 221 is thus formed in the buffer layer 220, exposing the portion of the top surface 216a of the top metal layer 216.

With reference to FIG. 4C, a deposition step is carried out to form a metal layer 618. In particular, an aluminum deposition step is performed (the portion of the metal layer 618 filling the through opening 221 forms the central portion 219a of the cap layer 218).

With reference to FIG. 4D, a masked etching step of the metal layer 618 is carried out in a per se known manner (e.g., by photolithography followed by dry etching), to remove selective portions of peripheral regions of the metal layer 618, thus forming the cap layer 218 having peripheral portions 219b and 219c, with respective cap edges 218b, 218c recessed with respect to the top metal edges 216b, 216c. The masked etching step of FIG. 4D includes forming an etching mask that protects a central portion of metal layer 618 from an etchant, leaving peripheral regions of the metal layer 618 unprotected. The protected central portion of metal layer 618 corresponds to the region 219a-219c previously described; the unprotected peripheral regions of the metal layer 618 cover the previously described outer region 229.

Alternatively, to the masked etch, other processes can be used, such as a lift-off process, or other patterning methods.

With reference to FIG. 4E, a deposition step of the second dielectric layer 222 is carried out (e.g., by CVD). The second dielectric layer 222 is, for example, made of silicon oxide and has the thickness tₛₒ in the range of 2 to 6 μm, in particular 4.5 μm.

With reference to FIG. 4F, a masked etching step of the second dielectric layer 222 is carried out (e.g., by photolithography followed by dry etching). A through opening 230 is thus formed through the entire thickness of the second dielectric layer 222, exposing the portion 219a of the cap layer 218.

With reference to FIG. 4G, the bonding structure 226 and the polymeric stack (i.e., organic passivation layer 224 and MC layer 225) are formed in per se known manner.

The device of FIG. 2A is thus obtained.

Finally, it is clear that modifications and variations may be made to what has been described and illustrated herein without thereby departing from the scope of the present invention, as defined in the attached claims.

In particular, it is further noted that the ranges indicated in the present disclosure are to be understood as including the boundaries values of the respective ranges.

The top and the bottom metal layer may have, in top-plan view on the xy plane, any shape chosen from among quadrangular, circular or generally polygonal, or other shapes. The respective shapes of the top and the bottom metal layer may be different from one another.

Even though the previous disclosure described the top and bottom metal layers as part of a galvanic insulator in the form of a capacitor, the embodiments apply equally to a galvanic insulator employing inductive coupling; in such a case, the top and bottom metal layers are windings (spirals) of a planar inductor and therefore includes metal turns.

Moreover, the disclosed embodiments can also find application in other technical fields different from galvanic isolation, such as electronic devices for power applications.

From what has been previously explained, the advantages that the embodiments afford are apparent.

In particular, an improvement in TTF is observed due to a reduction of electric field intensity in the polymeric stack.

As already observed, the recessed cap edges 218b, 218c with respect to the top metal edges 216b, 216c allow to decouple from one another the electric fields located at the top metal edges 216b, 216c and at the cap edges 218b, 218c, thus reducing or damping the electric field intensity in the polymeric stack in correspondence of these edges.

The increased thickness of the buffer layer 320 in the embodiment of FIG. 3 results in an increased total thickness of the inorganic passivation that further reduces the electric field intensity in the polymeric stack.

The above-described results allow therefore to mitigate the effect of ageing mechanisms registered during reliability tests, increasing product lifetime without introduction of added complexity in the fabrication process.

It will be noted that when a range is specified herein, the range explicitly includes the minimum and maximum values of the specified range.

1. An electronic device, comprising:
a solid body comprising a metallic structure having a top surface lying on a plane and having a thickness along a first direction orthogonal to the top surface;
a metal layer on the metallic structure, said metal layer comprising a central portion, a first peripheral portion and a second peripheral portion, the first and the second peripheral portion being at opposite ends of the central portion, the central portion being in direct electrical contact with the surface of the metallic structure, the first and the second peripheral portion being in physical and electrical continuity with the central portion;
a first insulating layer interposed between the metallic structure and the first and second peripheral portions of the metal layer;
wherein the metallic structure has at least a first lateral surface, transverse to said plane, externally delimiting a corresponding portion of the metallic structure; and the first peripheral portion of the metal layer has a respective first lateral surface, transverse to said plane; and
wherein the first lateral surface of the metal layer is recessed from the first lateral surface of the metallic structure along a second direction orthogonal to the first direction of a first distance equal to, or greater than, one micrometer.

2. The electronic device of claim 1, wherein said first distance is in a range of 2 to 31 micrometers.

3. The electronic device of claim 1, wherein said first distance is substantially equal to 2 micrometers.

4. The electronic device of claim 1, wherein said first distance is substantially equal to 31 micrometers.

5. The electronic device of claim 1, wherein said first insulating layer has a thickness, along the first direction, equal to, or greater than, 400 nanometers.

6. The electronic device of claim 1, wherein said first insulating layer has a thickness, along the first direction, equal to, or greater than, 2 micrometers.

7. The electronic device of claim 1, further comprising:
a second insulating layer on the first insulating layer and on part of the metal layer;
wherein the second insulating layer includes a second passing hole at least partially aligned, along the first direction, with the central portion of the metal layer, and extending through the second insulating layer up to said metal layer.

8. The electronic device of claim 7, further comprising:
a passivation layer extending above the second insulating layer and including a third passing hole at least partially aligned, along the first direction, with the second passing hole.

9. The electronic device of claim 7, further comprising a molding compound filling the second and third passing holes.

10. The electronic device of claim 1, further comprising a wire connection electrically bonded to the central portion of the metal layer.

11. The electronic device of claim 1, further including a galvanic isolation module, wherein said metallic structure is a plate of a capacitor of the galvanic isolation module.

12. The electronic device of claim 1, further including a galvanic isolation module, wherein said metallic structure is a spiral conductor of an inductor of the galvanic isolation module.

13. The electronic device of claim 1, wherein:
the metallic structure has at least a second lateral surface opposite to the first lateral surface along the second direction, the second lateral surface being transverse to said plane and externally delimiting a corresponding portion of the metallic structure; and
the second peripheral portion of the metal layer further includes a respective second lateral surface opposite to the first lateral surface along the second direction and extending transverse to said plane; and
wherein the second lateral surface of the metal layer is recessed from the second lateral surface of the metallic structure along a second direction orthogonal to the first direction by a second distance in a range of 2 to 31 micrometers.

14. The electronic device of claim 13, wherein said first and second distances have a same value.

15. An electronic device comprising:
a solid body comprising a metallic structure having a top surface lying on a plane and having a thickness along a first direction orthogonal to the top surface;
a metal layer on the metallic structure, comprising a central portion, a first peripheral portion and a second peripheral portion, the first and the second peripheral portion being at opposite ends of the central portion, the central portion being in direct electrical contact with the surface of the metallic structure, the first and the second peripheral portion being in physical and electrical continuity with the central portion; and
a first insulating layer interposed between the metallic structure and the first and second peripheral portions of the metal layer;
wherein the first insulating layer has a thickness, along the first direction, higher than 2 or equal to micrometers.

16. The electronic device of claim 15, wherein the thickness of the first insulating layer is smaller than or equal to 6 micrometers.

17. The electronic device of claim 16, further comprising a second insulating layer on the first insulating layer and on part of the metal layer, wherein the second insulating layer has a respective thickness greater than, or equal to, 2 micrometers and smaller than, or equal to, 6 micrometers.

18. The electronic device of claim 17, further comprising a polymeric layer on the second insulating layer.

19. The electronic device of claim 18, wherein a distance between the polymeric layer and the metallic structure is in a range of 4 to 12 μm.

20. The electronic device of claim 15, wherein the metallic structure has at least a first lateral surface, transverse to said plane, externally delimiting a corresponding portion of the metallic structure; and the first peripheral portion of the metal layer has a respective first lateral surface, transverse to said plane, wherein the first lateral surface of the metal layer is recessed from the first lateral surface of the metallic structure along a second direction orthogonal to the first direction of a first distance in a range of 2 to 31 micrometers.

21. A method of manufacturing an electronic device, comprising the steps of:
providing a solid body comprising a metallic structure having a top surface lying on a plane and having a thickness along a first direction orthogonal to the top surface;
forming a first insulating layer on the surface of the metallic structure;
forming a first passing hole through the first insulating layer up to a corresponding portion of the surface of the metallic structure; and
forming a metal layer within the first passing hole and on the first insulating layer, wherein forming the metal layer comprises: forming a central portion in direct electrical contact with the surface of the metallic structure through the first passing hole, forming a first peripheral portion at an end of the central portion and on the first insulating layer, and forming a second peripheral portion at an opposite end of the central portion and on the first insulating layer, the first and the second peripheral portion being formed in physical and electrical continuity with the central portion;
wherein the metallic structure has at least a first lateral surface transverse to said plane, externally delimiting a corresponding portion of the metallic structure;
wherein the first peripheral portion of the metal layer has a respective first lateral surface transverse to said plane; and
wherein the first lateral surface of the metal layer is formed recessed from the first lateral surface of the metallic structure along a second direction orthogonal to the first direction of a first distance equal to, or greater than, one micrometer.

22. The method of claim 21, wherein said first distance is in a range of 2 to 31 micrometers.

23. The method of claim 21, wherein said first distance is substantially equal to 2 micrometers.

24. The method of claim 21, wherein said first distance is substantially equal to 31 micrometers.

25. The method of claim 21, wherein the metallic structure has at least a first lateral surface transverse to said plane, externally delimiting a corresponding portion of the metallic structure, the first peripheral portion of the metal layer has a respective first lateral surface transverse to said plane, the first lateral surface of the metal layer is formed recessed from the first lateral surface of the metallic structure along a second direction orthogonal to the first direction of a first distance equal to, or higher than, 1 micrometer; and
the first insulating layer has a thickness, along the first direction, higher than 2 or equal to micrometers.

26. The method of claim 25, wherein the first distance is in a range of 2 to 31 micrometers, and the thickness of the first insulating layer is smaller than or equal to 6 micrometers.
